(19) United States
(12) Patent Application Publication
(10) Pub. No.: US 2014/0009857 A1
(43) Pub. Date: Jan. 9, 2014

(54) POWER SUPPLY DEVICE

(71) Applicant: HITACHI KOKI CO., LTD., Tokyo (JP)

(72) Inventor: Toshiyuki Suzuki, Ibaraki (JP)

(21) Appl. No.: 13/934,655

(22) Filed: Jul. 3, 2013

(30) Foreign Application Priority Data
Jul. 7, 2012 (JP) 2012-153141

(51) Int. Cl. H02H 3/08; H05K 7/20

(52) U.S. Cl. CPC H02H 3/08; H05K 7/20136
USPC 361/87; 361/690; 361/695

(57) ABSTRACT

A power supply device comprising: a plurality of battery units each having a protective unit, an output voltage from the plurality of battery units being configured to energize an electric power tool; and a drive-limiting unit provided in a current path of the battery unit of each row, wherein each protective unit stops energization from the battery unit of its row by the drive-limiting unit provided in the current path of the battery unit of its row, when the battery unit of its row has an error.

### CROSS-REFERENCE TO RELATED APPLICATIONS

This application claims priority from Japanese Patent Application No. 2012-153141 filed on Jul. 7, 2012, the entire contents of which are incorporated herein by reference.

### TECHNICAL FIELD

Aspects of the invention relate to a power supply device capable of energizing an electric apparatus using a battery voltage.

### BACKGROUND

In recent, cordless electric power tools using a battery pack (battery unit) are widely used. One battery cell of the lithium-ion secondary battery widely used for the cordless electric power tool has a low output voltage, for example, 3.6V, and a low capacity, for example, 1 Ah to 2 Ah. Therefore, a method of connecting a plurality of battery cells in series is used, thereby increasing the output voltage to 7.2V, 10.8V, 14.4V, 18V, 25.2V or 36V, etc. Further, for example, a method of connecting two battery cells of 1 Ah in parallel is used, thereby increasing the capacity to 2 Ah, or four battery cells of 1 Ah in parallel is used, thereby increasing the capacity to 4 Ah.

In the cordless electric power tool, if the battery voltage is increased, the output is also increased. Therefore, if the capacity of the battery pack is not high, the capacity becomes empty early. However, since the battery pack of the high voltage/high capacity is required to connect dozens or hundreds of battery cells in series or parallel, this leads to increase in weight, or increase in size so that it cannot be directly connected to the cordless electric power tool. Therefore, it has been proposed a system including a power supply device of which the battery pack of the high voltage/high capacity is separated from the electric tool, and the cordless electric power tool is connected to the power supply device via a connection adaptor (see JP-U-H03-62783 and JP-U-H07-3983).

If the power supply device including a plurality of battery units is used, since a residual capacity rate of each battery unit is not constant, an output control according to the state of each battery unit is required. Further, in a case where a plurality of electric apparatuses are energized, it is necessary to assure a long time for energizing the main electric apparatus, such as an electric power tool. In addition, since the battery pack of the high voltage/high capacity is large in size, it is required to reduce the burden on a user who wears the battery pack.

### SUMMARY

Aspects of the present invention has been made in view the above circumstances, and a first aspect of the present invention is to provide a power supply device capable of controlling its output according to a state of each battery unit in a case where the power supply device equipped with a plurality of battery units is used. Further, a second aspect of the present invention is to provide a power supply device capable of energizing a main electric apparatus for a long time in a case where a plurality of electric apparatuses are energized. In addition, a third aspect of the present invention is to provide a power supply device of a back-pack type capable of decreasing discomfort of a worker wearing a battery unit.

According to an aspect of the present invention, there is provided a power supply device including: a plurality of battery units each having a protective unit, an output voltage from the plurality of battery units being configured to energize an electric power tool; and a drive-limiting unit provided in a current path of the battery unit of each row, wherein each protective unit stops energization from the battery unit of its row by the drive-limiting unit provided in the current path of the battery unit of its row, when the battery unit of its row has an error.

According to another aspect of the present invention, there is provided a power supply device including: a battery unit; and a terminal configured to energize the electric power tool and an electric apparatus having a lower output than that of the electric power tool by using an output voltage of the battery unit.

According to another aspect of the invention, there is provided a power supply device of a back pack type, the power supply device including: an output section configured to be connected to an electric power tool; and at least one of a ventilating unit configured to ventilate a periphery of the power supply device and a heating-cooling unit configured to heat or cool a periphery of the power supply device.

Note that all arbitrary combinations of the above-described constituents, and all conversions of expression of the present invention, made among methods or systems, are also valid as the exemplary embodiments of the present invention.

Aspects of the present invention can realize the power supply device capable of controlling its output according to the state of each battery unit in the case where the power supply device equipped with the plurality of battery units is used, the power supply device capable of energizing the main electric apparatus for a long time in the case where the plurality of electric apparatuses are energized, and the power supply device of the back-pack type capable of decreasing discomfort of the worker when wearing the battery unit.

### BRIEF DESCRIPTION OF DRAWINGS

FIG. 1 is a diagram illustrating an entire configuration of a power supply system employing a power supply device 1 according to an embodiment of the present invention;

FIG. 2 is a front view of a connection terminal section for connecting the power supply device 1 with an external device;

FIG. 3 is a circuit diagram of the power supply device 1;

FIG. 4 is an enlarged front view of a main discharge terminal 21 in FIG. 2;

FIG. 5 is an enlarged front view of a low-voltage adaptor 81 and a high-voltage adapter 91 which are connected to the main discharge terminal 21;

FIG. 6 is an internal circuit diagram of the high-voltage adaptor 91;

FIG. 7 is an internal circuit diagram illustrating one example of the low-voltage adaptor 81; and

FIG. 8 is an internal circuit diagram illustrating another example of the low-voltage adaptor 81.

### DETAILED DESCRIPTION

Hereinafter, embodiments of the present invention will now be described with reference to the accompanying drawings. Note that all same or similar constituents or members in all drawings are given similar reference numerals or symbols, so as to avoid repetitive explanation. Note also that the embodiment does not intend to limit the scope of the present invention but exemplify the invention. All of the features and the combinations thereof described in the embodiment are not necessarily essential to the invention.

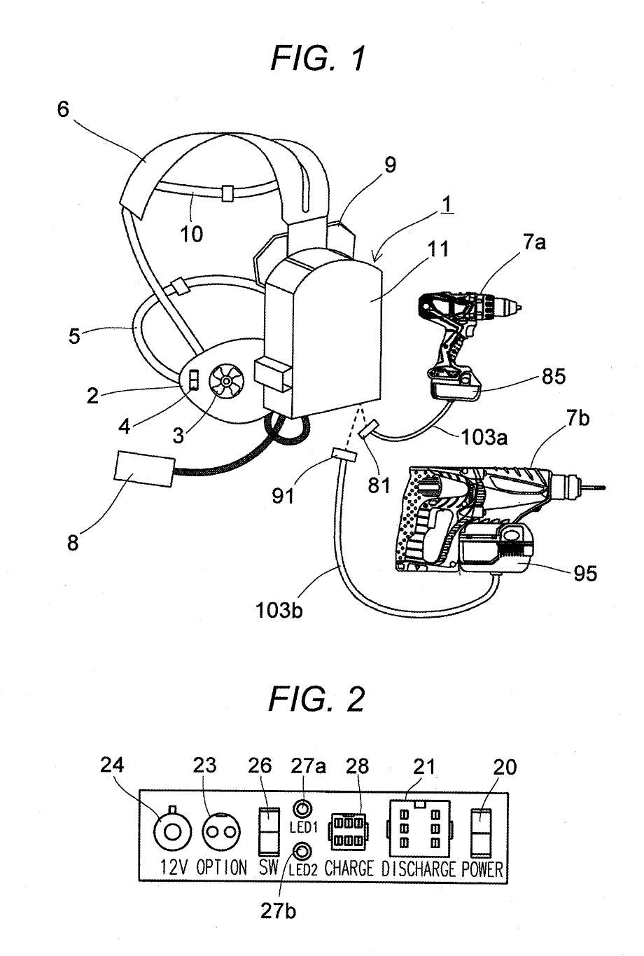

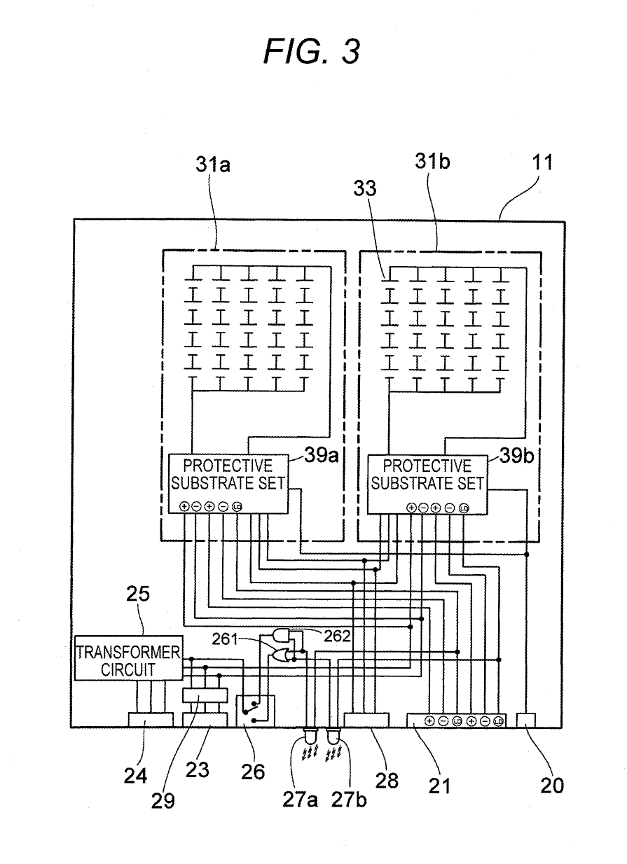

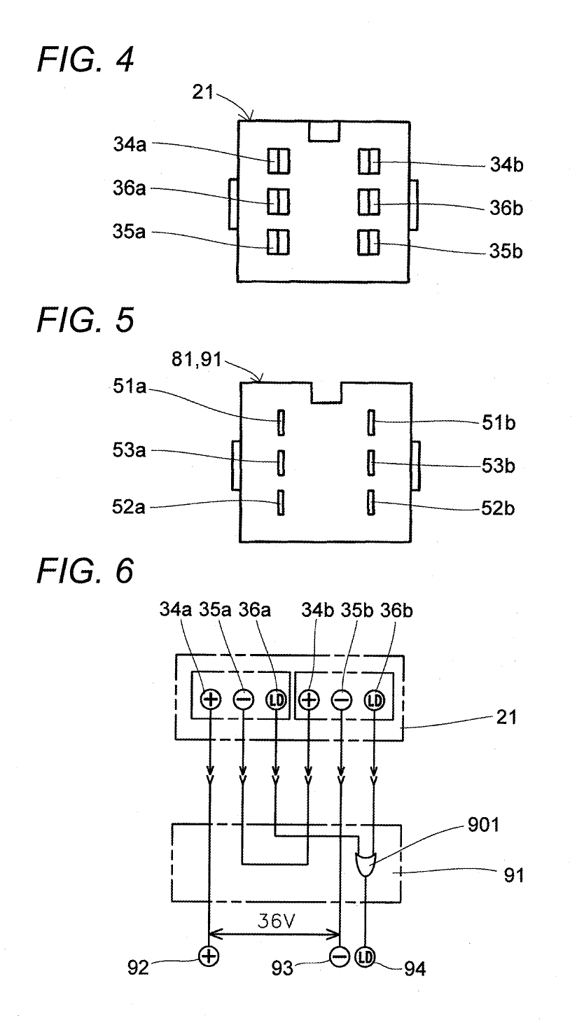

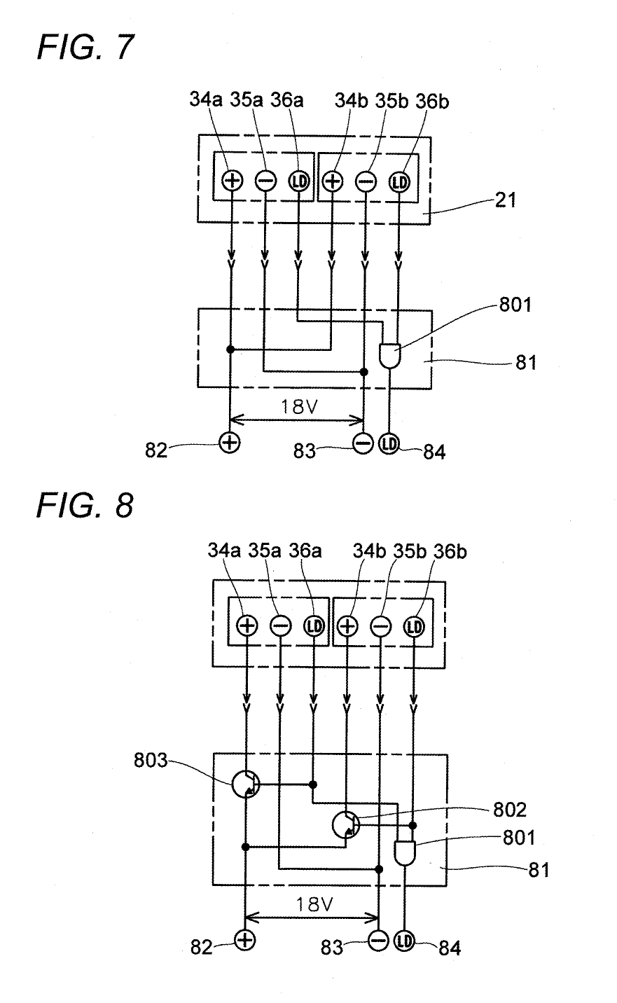

FIG. 1 is a diagram illustrating the whole configuration of a power supply system employing a power supply device 1 according to an embodiment of the present invention. FIG. 2 is a front view of a connection terminal section for connecting the power supply device 1 with an external device. The connection terminal section illustrated in the drawing is installed at a bottom surface of a housing 11 of the power supply device 1 in FIG. 1, for example. FIG. 3 is a circuit diagram of the power supply device 1 in the housing 11. FIG. 4 is an enlarged front view of a main discharge terminal 21 in FIG. 2. FIG. 5 is an enlarged front view of a low-voltage adaptor 81 and a high-voltage adapter 91 which are connected to the main discharge terminal 21. FIG. 6 is an internal circuit diagram of the high-voltage adaptor 91. FIG. 7 is an internal circuit diagram illustrating one example of the low-voltage adaptor 81. FIG. 8 is an internal circuit diagram illustrating another example of the low-voltage adaptor 81.

As illustrated in FIG. 1, the power supply device 1 is a back-pack type, and includes a housing 11 for receiving or housing battery packs 31a, 31b (FIG. 3) as a battery unit, the housing 11 being attached with a shoulder belt (harness) 6, a shoulder belt fixing belt 10 for stably fixing the shoulder belt 6 on a chest of a body, a back contact pad 9 functioning as a back contact portion, left and right waist contact pads 2, and a waist contact pad fixing belt 5 for stably fixing the left and right waist contact pads 2 on a waist of the body. Herein, the back contact pad 9 and the left and right waist contact pads 2 may be configured by one constitutional component, that is, may be a so-called back pack type.

As illustrated in FIG. 2, the power supply device 1 includes a power switch 20, the main discharge terminal 21, a charge terminal 28, informing units 27a, 27b, such as LED, a mode switching switch 26, an optional function connection terminal 23 (discharge terminal for option), and a general-purpose output socket 24 (transformation output terminal). The power switch 20 is an on/off switch of the power supply device 1. The main discharge terminal 21 is a terminal to be selectively connected to a low-voltage electric power tool 7a or a high-voltage electric power tool 7b, which are illustrated in FIG. 1. The charge terminal 28 is a terminal to be connected to a charger (not illustrated) to charge the battery packs 31a, 31b of the power supply device 1. The informing units 27a, 27b, such as LED, inform a user of a state of the battery packs 31a, 31b, and, for example, are turned on or off according to the presence or absence of the output from the battery packs 31a, 31b. The mode switching switch 26 switches between stopping or maintaining the output of the optional function connection terminal 23 and the general-purpose output socket 24 if a protective circuit for any one of the battery packs 31a, 31b is operated (e.g., residual capacity shortage). The optional function connection terminal 23 is provided to be connected to an electric apparatus separate from the low-voltage electric power tool 7a or the high-voltage electric power tool 7b. The general-purpose output socket 24 is a terminal capable of connecting a 12V apparatus, such as vehicular equipments, or a compact electronic apparatus which is driven by a general-purpose power supply terminal such as Universal Serial Bus (USB).

As illustrated in FIG. 3, the respective battery packs 31a and 31b includes a plurality of battery cells 33 which are connected in series to each other to generate a rated voltage of, for example, 18V (five battery cells are connected in series to each other if a single cell is 3.6V), in which the battery cells 33 connected in series to each other are connected in parallel with each other to increase its capacity. The battery packs 31a and 31b are equipped with protective substrate sets 39a, 39b having a function of monitoring errors, such as charge, overcharge, over discharge, or over current. As illustrated in FIGS. 4 and 6, positive electrodes 34a, 34b and negative electrodes 35a, 35b of the battery packs 31a, 31b are led to the main discharge terminal 21 by internal wiring illustrated in FIG. 3, and face the bottom surface of the housing 11, for example, as a connection hole. For example, the protective substrate sets 39a, 39b are configured to output a drive-limiting signal of a high level to signal output terminals 36a, 36b, at the errors, such as over discharge, of the battery packs 36a, 36b, and to output a signal of a low level to the signal output terminals 36a, 36b during normal operation. However, the signals to be output to the signal output terminals 36a, 36b may be opposite thereto.

As illustrated in FIG. 1, the low-voltage adaptor 81 is connected to the low-voltage electric power tool 7a by an adaptor cable 103a and a low-voltage tool-side adaptor 85. Further, the high-voltage adaptor 91 is connected to the high-voltage electric power tool 7b by an adaptor cable 103b and a high-voltage tool-side adaptor 95. As illustrated in FIG. 5, the low-voltage adaptor 81 and the high-voltage adaptor 91 have terminals 51a to 53a and 51b (pin shape) to 53b connected to the respective terminals (connection hole) of the main discharge terminal 21.

As illustrated in FIG. 6, in the high-voltage adaptor 91 (e.g., for 36V), the positive electrode 34a of the battery pack 31a is connected to a positive output terminal 92, and the negative electrode 35b of the battery pack 31b is connected to a negative output terminal 93, and the positive electrode 34b of the battery pack 31b is connected to the negative electrode 35a of the battery pack 31a. In addition, the drive-limiting signal output terminals 36a, 36b of the protective substrate sets 39a, 39b are used as an input of an OR gate 901, and an output terminal of the OR gate 901 is connected to an LD output terminal 94. Accordingly, a composite voltage (36V) formed by the series connection of the battery packs 31a, 31b is output from the high-voltage adaptor 91, and a logical sum of the drive-limiting signals of the protective substrate sets 39a, 39b is also output therefrom. That is, when the battery packs 31a, 31b are connected in series to each other, the drive-liming signal is output to the electric power tool side if at least one of the battery packs 31a, 31b has an error. In this instance, the protective substrate sets 39a, 39b sending the drive-limiting signal may directly interrupt the current output from the battery packs 31a, 31b. If there is no such a function, the electric power tool side receiving the drive-limiting signal may interrupt the current from the battery packs 31a, 31b.

As illustrated in FIG. 7, in the low-voltage adaptor 81 (e.g., for 18V), the positive electrodes 34a, 34b of the battery packs 31a, 31b are connected to a positive output terminal 82, and the negative electrodes 35a, 35b are connected to a negative output terminal 83. In addition, the drive-limiting signal output terminals 36a, 36b of the protective substrate sets 39a, 39b are used as an input of an AND gate 801, and an output terminal of the AND gate 801 is connected to an LD output terminal 84. Accordingly, a composite voltage (18V) formed by the parallel connection of the battery packs 31a, 31b is output from the low-voltage adaptor 81, and a logical product of the drive-limiting signals of the protective substrate sets 39a, 39b is also output therefrom. That is, when the battery packs 31a, 31b are connected in parallel with each other, the drive-limiting signal is output to the electric power tool side if both the battery packs 31a, 31b have errors. When only one of the battery packs 31a, 31b has an error, the electric power tool is continuously energized from the other normal battery pack. In this instance, the protective substrate, which sends the drive-limiting signal, of the protective substrate sets 39a, 39b may directly interrupt the current output from one battery pack. If there is no such a function, as illustrated in FIG. 8, the low-voltage adaptor 81 is provided with drive-limiting switches (switching element) 802, 803, and the drive-limiting switches 802, 803 may be turned off by the drive-limiting signal.

As described above, the power supply device 1 supplies low voltages (18V) in two lines to the main discharge terminal 21 connecting the low-voltage adaptor 81 and the high-voltage adaptor 91 as the output, and transforms it into a low voltage (18V) or a high voltage (36V) in one line by a wire connection (internal circuit) of the low-voltage adaptor 81 or the high-voltage adaptor 91 to supply it to the low-voltage electric power tool 7a or the high-voltage electric power tool 7b. That is, the power supply device 1 can output two kinds of voltages, the low voltage (18V) and the high voltage (36V), from the main discharge terminal 21 only by changing the adaptor. As an example, if the battery packs 31a, 31b are 18V, 5 Ah rating, respectively, the capacity becomes 10 Ah when the low-voltage adaptor 81 (18V) is used, while the capacity becomes 5 Ah when the high-voltage adaptor 91 (36V) is used.

As illustrated in FIG. 1, the waist contact pad 2 is equipped with a fan 3, which is an optional equipment, functioning as a cooling unit for cooling the body of the worker. The fan 3 is energized by, for example, 18V, from the battery packs 31a, 31b via the optional function connection terminal 23. The fan 23 is configured to receive the air from the exterior and to discharge the heat stayed at a back portion of the worker. The worker can turn on or off the fan 3 using a fan power switch 4 which is installed on the waist contact pad 2. This can lead to decrease the discomfort of the worker due to the heat generated from the battery packs 31a, 31b. The fan 3 may be installed in, for example, the back contact pad 9 at the upper portion of the housing 11. As the cooling unit, a Peltier element may be installed in, for example, the back contact pad 9, instead of the fan 3 or in addition to the fan 3. As the Peltier element is disposed between the back of the worker and the housing 11 receiving the battery packs 31a, 31b therein so that the back side becomes a heat absorbing surface (cooling surface), it can decrease the discomfort of the worker due to the heat generated from the battery packs 31a, 31b. Further, it can employ a configuration of heating the worker in a cold climate region by installing the Peltier element or the electrically-heated wire between the back of the worker and the housing 11 receiving the battery packs 31a, 31b so that the back side becomes a heating surface.

As illustrated in FIG. 1, the power supply device 1 is connected to a small electric apparatus 8 for general-purpose use. As illustrated in FIG. 3, the output voltage of a transformer circuit 25 which steps down the voltage (herein, 18V in voltage by the parallel connection) of the battery packs 31a and 31b is output from the general-purpose output socket 24, and the electric apparatus 8 for general-purpose use is energized by the battery packs 31a and 31b via the output socket 24. The electric apparatus 8 for general-purpose use is, for example, a 12V-type vehicular equipment which can be commercially available at a low price, or a USB, and includes a cleaner, an LED light, polisher, a cell phone, a general-purpose inverter, etc. In the case where the 12V-type vehicular equipment is used, if an electric power source is taken from a vehicle, it may lead to shortage of the battery unless an engine of the vehicle is started. Further, since a cable for the 12V-type vehicular equipment is short, there is inconvenience such as it is difficult to do work. If the power supply device 1 is provided with the general-purpose output socket 24 to use the 12V-type vehicular equipment, as illustrated in this embodiment, the above-described problem can be solved, and it can be useful as a power source for emergency. For example, if the battery packs 31a and 31b are charged, the cell phone or the like can be charged or supplied with electricity, or the general-purpose inverter can be driven to supply 100V.

In this instance, the fan 3 and the small electric apparatus 8 for general-purpose use can be switched by the mode switching switch 26 between an optional power saving mode, in which if either of the battery packs 31a, 31b has an error or is empty, it is turned off, and an optional non-power saving mode, in which if both the battery packs 31a, 31b have an error or is empty, it is turned off. In the optional power saving mode, an output signal (logical sum of the drive-limiting signals of the protective substrate sets 39a, 39b) of the OR gate 261 is output to a mode control section 29 and the transformer circuit 25. In the optional non-power saving mode, an output signal (logical product of the drive-limiting signals of the protective substrate sets 39a, 39b) of the AND gate 262 is output to the mode control section 29 and the transformer circuit 25. In the optional non-power saving mode, when only either of the battery packs 31a, 31b has an error, the fan 3 and the small electric apparatus 8 for general-purpose use are continuously energized from the other normal battery pack (the mode control section 29 and the transformer circuit 25 continuously output the voltage to the optional function connection terminal 23 and the general-purpose output socket 24). In this instance, one of the protective substrate sets 39a, 39b which emits the drive control signal interrupts the current output from its own battery pack. In the optional power saving mode, if the output from at least one of the battery packs 31a, 31b is stopped, at least one of the fan 3 and the small electric apparatus 8 for general-purpose use is stopped from being energized (the mode control section 29 and the transformer circuit 25 interrupt the voltage output to at least one of the optional function connection terminal 23 and the general-purpose output socket 24).

According to this embodiment, the following effects can be obtained.

(1) At the series connection of the battery packs 31a, 31b, since the electric power tool or the like is stopped from the energization in the case where the protective circuit of at least one of the battery packs 31a, 31b is driven, it is possible to prevent the battery packs from being overloaded.

(2) At the parallel connection of the battery packs 31a, 31b, even in the case where the output from one of the battery packs 31a, 31b is restricted, the electric power tool is continuously energized by the other normal battery pack, so that it is possible to assure a long time period for energization.

(3) Since the cooling unit is connected to the optional function connection terminal 23, separately from the electric power tool, it is possible to decrease the discomfort of the worker due to the heat generated from the battery packs 31a, 31b.

(4) Since the general-purpose output socket 24 which can energize the 12V-type vehicular equipment or the USB, which are available at a low price, is provided, the convenience is high and its general versatility as the power supply device is also high.

(5) Since the optional power saving mode is embedded in which when the protective circuit of either of the battery packs 31a, 31b is operated, at least one of the fan 3 and the small electric apparatus 8 for general-purpose use is stopped from the energization, it is possible to assure a long time period for energizing the main electric power tool. Meanwhile, the optional non-power saving mode can be selected in which the fan 3 and the small electric apparatus 8 for general-purpose use can be continuously energized until the output of both the battery packs 31a, 31b is stopped, so that it can be flexible in response to the needs of the worker.

(6) Since the worker is informed of state of the battery packs 31a, 31b by the informing unit 27a, 27b, such as LED, it is convenient that the worker can always figure out the state of the battery packs 31a, 31b.

It will be understood by those skilled in the art that the present invention has been described based on the embodiment, but various modifications for each constituent element or each process in the embodiment can be made without departing from the spirit or scope of the invention claimed in the claims. Modifications will now be described.

If the optional power saving mode of the embodiment is applied to a case in which there is one battery pack, it may be configured to maintain the energization to the electric power tool from the battery pack and to stop the energization to at least one of the fan 3 and the electric apparatus 8 for general-purpose use from the battery pack, when a ratio (residual capacity rate) of the output voltage to the rated voltage is lower than a predetermined value.

The informing units 27a, 27b, such as LED, may be provided to the shoulder belt 6 or the waist contact pad 2, or the low-voltage tool-side adaptor 85 or the high-voltage tool-side adaptor 95, instead of the housing 11 or in addition to the housing 11. Alternatively, other informing units, such as alarm, may be employed or be used in combination with the informing units 27a, 27b.

The present invention provides illustrative, non-limiting aspects as follows:

(1) According to a first aspect, there is provided a power supply device including: a plurality of battery units each having a protective unit, an output voltage from the plurality of battery units being configured to energize an electric power tool; and a drive-limiting unit provided in a current path of the battery unit of each row, wherein each protective unit stops energization from the battery unit of its row by the drive-limiting unit provided in the current path of the battery unit of its row, when the battery unit of its row has an error.

(2) According to a second aspect, there is provided the power supply device according to the first aspect, wherein the plurality of battery units are connected in parallel with each other, and wherein, when the protective unit of the battery unit of one row emits a drive-limiting signal and the protective unit of the battery unit of another row does not emit a drive-limiting signal, energization from the battery unit of the one row is stopped and the electric power tool is energized from the battery unit of the other row.

(3) According to a third aspect, there is provided the power supply device according to the first aspect, wherein the plurality of battery units are connected in series to each other, and wherein the output of the voltage is stopped when the protective unit of at least one of the battery units emits a drive-limiting signal.

(4) According to a fourth aspect, there is provided the power supply device according to the first aspect, further including an adaptor provided between the plurality of battery units and the electric power tool, wherein the adaptor is configured to connect the plurality of battery units in parallel and includes the drive-limiting unit.

(5) According to a fifth aspect, there is provided the power supply device according to the first aspect, wherein series connection or parallel connection of the plurality of battery units is configured to be selected by a connection unit, and wherein, when the plurality of battery units are connected in series to each other, the energization to the electric power tool is stopped if the protective unit of at least one battery unit emits the drive-limiting signal.

(6) According to a sixth aspect, there is provided the power supply device according to the fourth aspect, wherein the power supply device is configured to energize the electric power tool and an electric apparatus other than the electric power tool, and wherein, when the plurality of battery units are connected in parallel with each other and the protective unit of the battery unit of at least one row emits the drive-limiting signal, the electric power tool is energized and the energization to the electric apparatus is stopped.

(7) According to a seventh aspect, there is provided the power supply device according to the fourth aspect, wherein the power supply device is configured to energize the electric power tool and an electric apparatus other than the electric power tool, and wherein, when the plurality of battery units are connected in parallel with each other and the protective unit of the battery unit of at least one row emits the drive-limiting signal, the electric power tool is energized, and the energization to the electric apparatus is stopped if a mode switching switch is in a first state but the electric apparatus is energized if the mode switching switch is in a second state.

(8) According to an eighth aspect, there is provided the power supply device according to the second aspect, further including a logical circuit configured to execute a predetermined logical operation on the drive-limiting signal from the protective unit of each battery unit.

(9) According to a ninth aspect, there is provided the power supply device according to the first aspect, further including an informing unit configured to inform presence or absence of the drive-limiting signal from the protective unit of each battery unit.

(10) According to a tenth aspect, there is provided the power supply device according to the ninth aspect, further including an adaptor configured to connect an electric apparatus with the power supply device.

(11) According to an eleventh aspect, there is provided the power supply device according to the first aspect, wherein the power supply device is a back pack type, and wherein the power supply device further comprises a cooling unit which is separate from the electric apparatus.

(12) According to a twelfth aspect, there is provided a power supply device including: a battery unit; and a terminal configured to energize the electric power tool and an electric apparatus having a lower output than that of the electric power tool by using an output voltage of the battery unit.

(13) According to a thirteenth aspect, there is provided the power supply device according to the twelfth aspect, wherein the power supply device is configured to maintain energization to the electric power tool from the battery pack and to stop energization to the electric apparatus from the battery pack, when a ratio of an actual output voltage to a rated voltage of the battery unit is lower than a predetermined value.

(14) According to a fourteenth aspect, there is provided A power supply device of a back pack type, the power supply device including: an output section configured to be connected to an electric power tool; and at least one of a ventilating unit configured to ventilate a periphery of the power supply device and a heating-cooling unit configured to heat or cool a periphery of the power supply device.

(15) According to a fifteenth aspect, there is provided the power supply device according to the fourteenth aspect, wherein the ventilating unit is configured to vent a back contact portion of the power supply device.

(16) According to a sixteenth aspect, there is provided the power supply device according to the fourteenth aspect, wherein the ventilating unit includes a fan.

(17) According to a seventeenth aspect, there is provided the power supply device according to the sixteenth aspect, wherein the fan is provided in a back contact pad portion of the power supply device.

(18) According to an eighteenth aspect, there is provided the power supply device according to the sixteenth aspect, wherein the fan is provided in a waist or shoulder harness.

(19) According to a nineteenth aspect, there is provided the power supply device according to the fourteenth aspect, wherein the heating-cooling unit includes an electrically-heated wire or a Peltier element.

(20) According to a twentieth aspect, there is provided the power supply device according to nineteenth aspect, wherein the electrically-heated wire or the Peltier element is provided in a back contact portion of the power supply device.

Note that all arbitrary combinations of the above-described constituents, and all conversions of expression, made among methods or systems, are also included in the present invention.

What is claimed is:

1. A power supply device comprising:
a plurality of battery units each having a protective unit, an output voltage from the plurality of battery units being configured to energize an electric power tool; and
a drive-limiting unit provided in a current path of the battery unit of each row,
wherein each protective unit stops energization from the battery unit of its row by the drive-limiting unit provided in the current path of the battery unit of its row, when the battery unit of its row has an error.

2. The power supply device according to claim 1,
wherein the plurality of battery units are connected in parallel with each other, and
wherein, when the protective unit of the battery unit of one row emits a drive-limiting signal and the protective unit of the battery unit of another row does not emit a drive-limiting signal, energization from the battery unit of the one row is stopped and the electric power tool is energized from the battery unit of the other row.

3. The power supply device according to claim 1,
wherein the plurality of battery units are connected in series to each other, and
wherein the output of the voltage is stopped when the protective unit of at least one of the battery units emits a drive-limiting signal.

4. The power supply device according to claim 1, further comprising an adaptor provided between the plurality of battery units and the electric power tool,
wherein the adaptor is configured to connect the plurality of battery units in parallel and includes the drive-limiting unit.

5. The power supply device according to claim 1,
wherein series connection or parallel connection of the plurality of battery units is configured to be selected by a connection unit, and
wherein, when the plurality of battery units are connected in series to each other, the energization to the electric power tool is stopped if the protective unit of at least one battery unit emits the drive-limiting signal.

6. The power supply device according to claim 4,
wherein the power supply device is configured to energize the electric power tool and an electric apparatus other than the electric power tool, and
wherein, when the plurality of battery units are connected in parallel with each other and the protective unit of the battery unit of at least one row emits the drive-limiting signal, the electric power tool is energized and the energization to the electric apparatus is stopped.

7. The power supply device according to claim 4,
wherein the power supply device is configured to energize the electric power tool and an electric apparatus other than the electric power tool, and
wherein, when the plurality of battery units are connected in parallel with each other and the protective unit of the battery unit of at least one row emits the drive-limiting signal, the electric power tool is energized, and the energization to the electric apparatus is stopped if a mode switching switch is in a first state but the electric apparatus is energized if the mode switching switch is in a second state.

8. The power supply device according to claim 2, further comprising a logical circuit configured to execute a predetermined logical operation on the drive-limiting signal from the protective unit of each battery unit.

9. The power supply device according to claim 1, further comprising an informing unit configured to inform presence or absence of the drive-limiting signal from the protective unit of each battery unit.

10. The power supply device according to claim 9, further comprising an adaptor configured to connect an electric apparatus with the power supply device.

11. The power supply device according to claim 1,
wherein the power supply device is a back pack type, and
wherein the power supply device further comprises a cooling unit which is separate from the electric apparatus.

12. A power supply device comprising:
a battery unit; and
a terminal configured to energize the electric power tool and an electric apparatus having a lower output than that of the electric power tool by using an output voltage of the battery unit.

13. The power supply device according to claim 12,
wherein the power supply device is configured to maintain energization to the electric power tool from the battery pack and to stop energization to the electric apparatus from the battery pack, when a ratio of an actual output voltage to a rated voltage of the battery unit is lower than a predetermined value.

14. A power supply device of a back pack type, the power supply device comprising:
an output section configured to be connected to an electric power tool; and
at least one of a ventilating unit configured to ventilate a periphery of the power supply device and a heating-cooling unit configured to heat or cool a periphery of the power supply device.

15. The power supply device according to claim 14,
wherein the ventilating unit is configured to vent a back contact portion of the power supply device.

16. The power supply device according to claim 14,
wherein the ventilating unit includes a fan.

17. The power supply device according to claim 16,
wherein the fan is provided in a back contact pad portion of the power supply device.

18. The power supply device according to claim 16,
wherein the fan is provided in a waist or shoulder harness.

19. The power supply device according to claim 14,
wherein the heating-cooling unit includes an electrically-heated wire or a Peltier element.

20. The power supply device according to claim 19,
wherein the electrically-heated wire or the Peltier element is provided in a back contact portion of the power supply device.
